(19) United States
(12) Patent Application Publication
(10) Pub. No.: US 2009/0126976 A1
(43) Pub. Date: May 21, 2009

(54) FLEXIBLE WIRING BOARD, METHOD OF PRODUCING THE SAME AND IMAGING DEVICE

(75) Inventor: Akihisa IIDA, Kurokawa-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/274,997

(22) Filed: Nov. 20, 2008

(30) Foreign Application Priority Data
Nov. 21, 2007 (JP) 2007-302045

(51) Int. Cl. H05K 1/00; H05K 3/00

(52) U.S. Cl. 174/254; 29/829

(57) ABSTRACT

A flexible wiring board is formed with a first mounting surface, a first erected surface portion, a relay portion, a second erected surface portion and a second mounting surface. The first erected surface portion and the second erected surface portion are positioned on the same plane. The second mounting surface is fixed. When the first mounting surface is moved in the X-axis direction, the force in the X-axis direction acts on the relay portion as a force from a direction outside of the plane since the first erected surface portion and the second erected surface portion are positioned on the same plane. Therefore, the relay portion is bent and a suppressed reaction force acts on the first mounting surface and on the second mounting surface.

### CROSS-REFERENCE TO RELATED APPLICATION

This application claims priority under 35 USC 119 from Japanese Patent Application No. 2007-302045, the disclosure of which is incorporated by reference herein.

### BACKGROUND OF THE INVENTION

1. Field of the Invention

The present invention relates to a flexible wiring board, a method of producing the same and an imaging device.

2. Description of the Related Art

Digital cameras are provided with a blurring mechanism (an image stabilization mechanism) for correcting the blurring of a picture caused by unintentional movement of the hands in taking a picture (camera shake). The blurring correction mechanism so works that a moving part mounting an imaging element or an optical part moves accompanying the movement of the camera caused by unintentional movement of the hands, and signals are processed by a circuit board fixed in the camera body to suppress the blurring of a picture. The moving part is moved by a voice coil motor or a stepping motor.

Here, a flexible wiring board having a fold (folded portion) is used for electrically connecting the moving portion to the circuit board while suppressing the load of movement of the moving portion (see, for example, JP-A No. 2007-122020). According to the flexible wiring board of JP-A No. 2007-122020, a flexible substrate is folded at a plurality of portions and are erected from the flat portion forming a nearly U-shaped fold.

With the flexible wiring board of JP-A No. 2007-122020, however, it is difficult to maintain the folds at a folded angle of 90° constant in the step of assembling. When the flexible substrate is mounted, however, the moving part and the circuit board are so arranged that the folded angle of the folds become 90° causing a reaction force to act on the folds.

### SUMMARY OF THE INVENTION

The present invention is to provide a flexible wiring board capable of suppressing the reaction force of a flexible substrate that is used being folded and an imaging device.

The flexible wiring board according to a first aspect of the present invention includes: a flexible substrate including a first flexible substrate portion and a second flexible substrate portion divided by a slit and connected by a relay substrate portion, the first flexible substrate portion including a first fold (folded portion) and a first erected surface portion which is provided on the side of the relay substrate portion relative to the first fold, and which is erected from (is fold and stands up at) the first fold, the second flexible substrate portion including a second fold (folded portion) and a second erected surface portion which is provided on the side of the relay substrate portion relative to the second fold, and which is erected from the second fold; a first mounting surface provided at a side opposite to the first erected surface portion relative to the first fold and on which a first electrode is mounted; a second mounting surface provided at a side opposite to the second erected surface portion relative to the second fold and on which a second electrode is mounted; and a wiring portion which is mounted on the first mounting surface, the first erected surface portion, the relay substrate portion, the second erected surface portion and the second mounting surface, and which connects the first electrode to the second electrode.

According to the above configuration in which the first erected surface portion and the second elected surface position are positioned on the same plane, when the force in a direction at right angles with the first fold and the second fold acts on the first mounting surface and the second mounting surface via end portions, the force acts on the relay substrate portion as a force from a direction outside of the plane. Here, the relay substrate portion is more readily bent by the force acting from the direction outside of the plane than the force acting from the direction inside of the plane. Therefore, since the relay substrate portion is bent, the reaction force that acts on the first mounting surface and on the second mounting surface from the first erected surface portion and the second erected surface portion may be suppressed.

Further, if the force acts on the first mounting surface and the second mounting surface in parallel with the first fold and the second fold via the first erected surface portion and the second erected surface portion, then a force acts on the relay substrate portion in the direction inside of the plane. However, since the first erected surface portion and the second erected surface portion can be displaced in the direction inside of the plane by the size of the slit, the reaction force that acts on the first mounting surface and on the second mounting surface from the first erected surface portion and the second erected surface portion may be suppressed.

In the flexible wiring board according to the first aspect of the invention, the slit may be formed in a U-shape, the inside of the U-shaped slit may serve as the second flexible substrate portion, the outside thereof may serve as the first flexible substrate portion, and the wiring portion may be arranged on the two first flexible substrate portions in a divided manner.

According to the above configuration, the wiring portion is divided between the two first flexible substrate portions and, therefore, the divided wiring portions have a narrow width. Therefore, the width of the relay substrate becomes narrow, the length of the slit increases, the load decreases when the first flexible substrate portion and the second flexible substrate portion move in a direction intersecting the lengthwise direction of the slit, facilitating the movement of the first flexible substrate portion and the second flexible substrate portion.

In the flexible wiring board according to the first aspect of the invention, an auxiliary slit may be formed cutting into the central portion of the second flexible substrate portion from the relay substrate portion and leaving the second mounting surface, and the wiring portions may be formed on both sides of the auxiliary slit. According to this configuration, the number of slits increases in the direction in which the second flexible substrate portion moves facilitating the second flexible substrate portion to easily move.

In the flexible wiring board according to the first aspect of the invention, a third fold may be provided in the upper part of the first erected surface portion and in the upper part of the second erected surface portion and traversing the slit. According to the above configuration, slits are formed in the first erected surface portion and in the second erected surface portion. When, for example, the first electrode moves in a direction to come in contact with, or separate away from, the second electrode, the movement is not suppressed by the relay substrate portion, and a decreased load of movement is exerted on the first electrode.

In the flexible wiring board according to the first aspect of the invention, the relay substrate portion may be provided at both ends of the slit to connect the first flexible substrate portion and the second flexible substrate portion together, and the wiring portion may be arranged being divided on the two relay substrate portions.

According to the above configuration, when the first electrode or the second electrode moves in the lengthwise direction of the slit, a set of opposing first flexible substrate portions or a set of opposing second flexible substrate portions undergoes a deformation like a parallelogram, permitting the first electrode or the second electrode to move without exerting an excess of load thereon.

Further, when the first electrode or the second electrode moves in a direction that intersects the lengthwise direction of the slit, movement becomes easy since movements of the first flexible substrate portion and the second flexible substrate portion are not hindered owing to the slit. Therefore, the first electrode or the second electrode can be easily moved in two directions.

In the flexible wiring board according to the first aspect of the invention, the relay substrate may be folded along the lengthwise direction of the slit, and an angle formed between (angle subtended by) the first erected surface portion and the second erected surface portion may be set to be the right angle. According to the above configuration, the angle between the first erected surface portion and the second erected surface portion is the right angle. When the first flexible substrate portion or the second flexible substrate portion is to be moved, therefore, it becomes easy to move the first erected surface portion and the second erected surface portion independently of each other. Therefore, the first flexible substrate portion and the second flexible substrate portion can be easily moved.

An imaging device may be constituted by the flexible wiring board of any one of the above configurations, an imaging element connected to the first electrode, a driving unit to which the second electrode is connected and fixed and drives the imaging element, and a moving unit that moves the imaging element in the two axial directions on a plane of movement.

According to the above configuration, the second electrode is fixed to the driving unit and the first electrode is allowed to move. Here, a reaction force is not likely to act on the first electrode or on the second electrode of the flexible wiring board; i.e., the first electrode or the second electrode easily displaces, and the imaging element is easily moved by the moving unit on the plane of movement. This enhances the moving precision of the imaging element for correcting blurring of the imaging device, and improves the precision of image stabilization of the imaging device.

The reaction force is not likely to act on the first electrode or the second electrode mounting the imaging element. Therefore, when, for example, means for moving the first electrode or the second electrode is a motor, the size of the motor can be reduced by suppressing the output, and the imaging device can be realized in a small size.

A method of producing a flexible wiring board according to a second aspect of the invention includes: providing a flexible substrate; forming a slit in the flexible substrate that divides the flexible substrate into a first flexible substrate portion and a second flexible substrate portion, but leaves a relay substrate portion that connects the first flexible substrate portion to the second flexible substrate portion; providing a first fold on the first flexible substrate portion, erecting a portion of the first flexible substrate portion on the side of the relay substrate portion relative to the first fold to form a first erected surface portion, and providing a first mounting surface on a side opposite the first erected surface portion relative to the first fold, on which a first electrode is provided; providing a second fold on the second flexible substrate portion, erecting a portion of the second flexible substrate portion on the side of the relay substrate portion relative to the second fold to form a second erected surface portion, and providing a second mounting surface on a side opposite the second erected surface portion relative to the second fold on which a second electrode is provided; and providing a wiring portion on the first mounting surface, the first erected surface portion, the relay substrate portion, the second erected surface portion and the second mounting surface to connect the first electrode to the second electrode.

Being constituted as described above, the invention makes it possible to suppress the reaction force of the flexible substrate that is used being folded.

### BRIEF DESCRIPTION OF THE DRAWINGS

FIG. 1 is an exploded view of a digital camera according to a first embodiment of the present invention;

FIG. 2A is a perspective view of an imaging module according to the first embodiment of the invention, and FIG. 2B is a an exploded view thereof;

FIGS. 3A and 3B are schematic views of before and after the flexible wiring board according to the first embodiment of the invention is folded;

FIG. 4A is a schematic view illustrating a flexible wiring board of Comparative Example 1, and FIG. 4B is a schematic view illustrating a flexible wiring board of Comparative Example 2;

FIG. 5 is a graph illustrating a relationship between the amount of displacement of the flexible wiring board and the reaction force that acts;

FIGS. 6A and 6B are schematic views illustrating another example of the flexible substrate according to the first embodiment of the invention;

FIGS. 7A and 7B are schematic views of before and after the flexible wiring board according to a second embodiment of the invention is folded;

FIGS. 8A and 8B are schematic views of before and after the flexible wiring board according to another example of the second embodiment of the invention is folded;

FIGS. 9A to 9D are schematic views of after the flexible wiring board according to a third embodiment of the invention is folded;

FIGS. 10A and 10B are schematic views of before and after the flexible wiring board according to a fourth embodiment of the invention is folded;

FIGS. 11A and 11B are schematic views illustrating a state where the flexible wiring board according to the fourth embodiment of the invention is moving; and

FIG. 12A and 12B are schematic views of before and after the flexible wiring board according to a fifth embodiment of the invention is folded.

### DETAILED DESCRIPTION OF THE INVENTION

A flexible wiring board and an imaging device according to a first embodiment of the present invention will now be described with reference to the drawings.

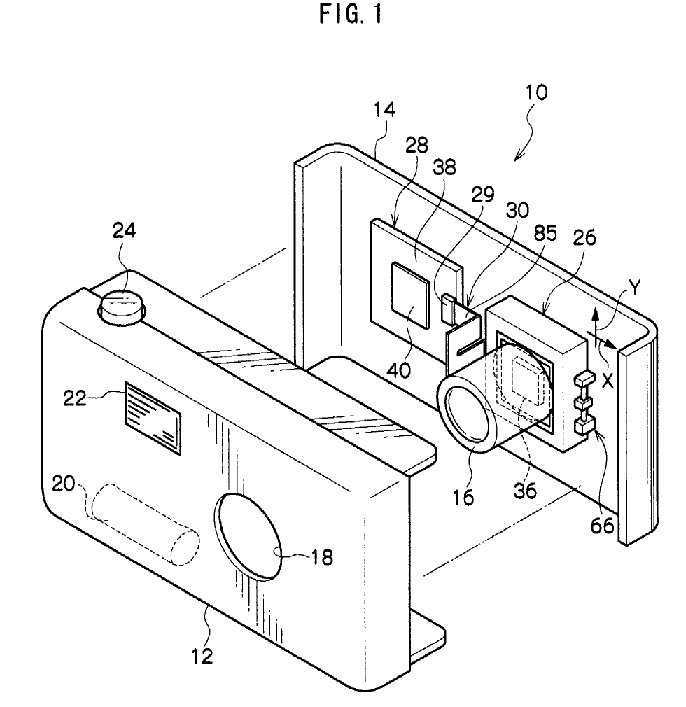

FIG. 1 illustrates a digital camera 10 which is an imaging device. The digital camera 10 has a front cover 12 and a rear cover 14 constituting the main body of the digital camera 10.

The front cover 12 has an opening in which a lens 16 is inserted for forming an image of a subject. On the inside of the front cover 12, there are provided a power source unit 20 for feeding electric power to various portions of the digital camera 10, a flush device 22 that emits light as required at the time of taking a picture, and a switch button 24 for starting the imaging operation.

On the inside of the rear cover 14, on the other hand, there is provided an imaging module 26 having a CCD (charge coupled device) 36 that receives light incident from the lens 16 and converts it into imaging data. In the imaging module 26, a flexible wiring board 30 is arranged forming a predetermined circuit pattern and the CCD 36 is mounted. From one side surface of the imaging module 26 (left side on the surface of the paper) is protruding a free end of the flexible wiring board 30 (end opposite to the side on where the CCD 36 is mounted).

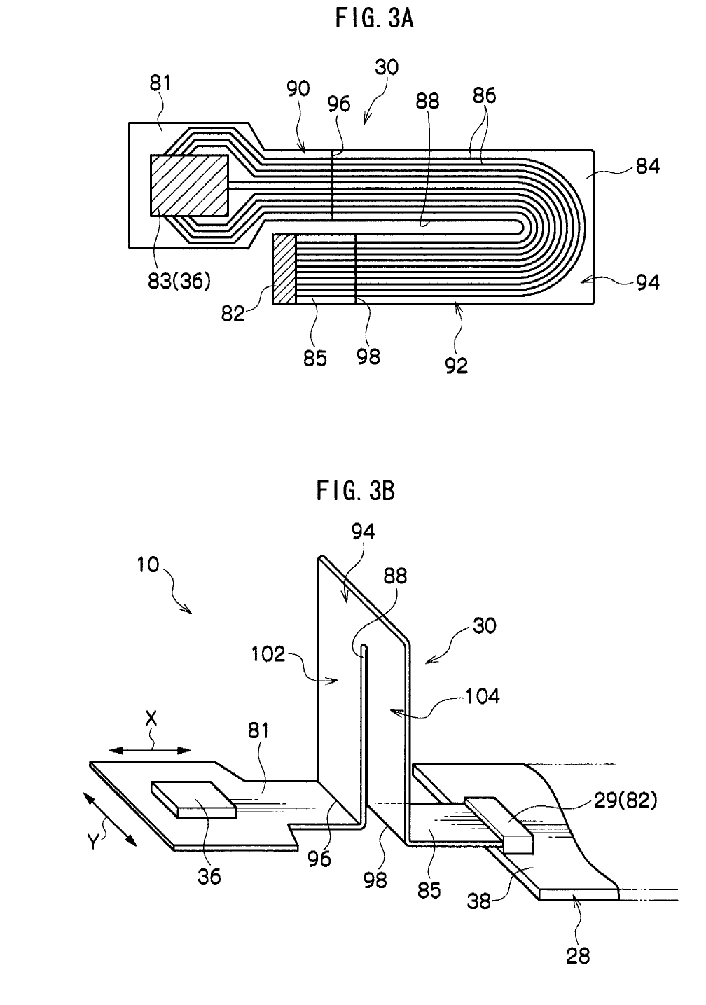

A connection terminal portion 82 (see FIG. 3A) comprising a plurality of terminals at the free end of the flexible wiring board 30 is connected to a connector 29 of the type of upper contacts provided in a driving circuit 28 that forms a predetermined circuit pattern and drives the imaging module 26. The imaging module 26 and the driving circuit 28 are thus electrically connected together. The lens 16 is arranged on the front surface side of the CCD 36 in the imaging module 26.

The driving circuit 28 is provided with a program unit 40 comprising an IC or the like on a rigid substrate 38 forming a predetermined circuit pattern. Upon depressing the switch button 24, the program unit 40 drives an automatic focusing mechanism that is not shown to move the lens 16 in a direction of focusing point and, further, drives the CCD 36 to take in the picture data so as to store the picture data in storage means such as an SD card or the like that is not shown.

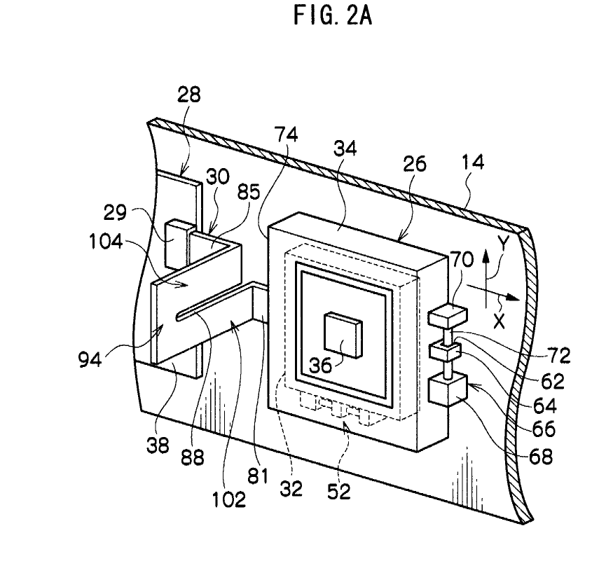

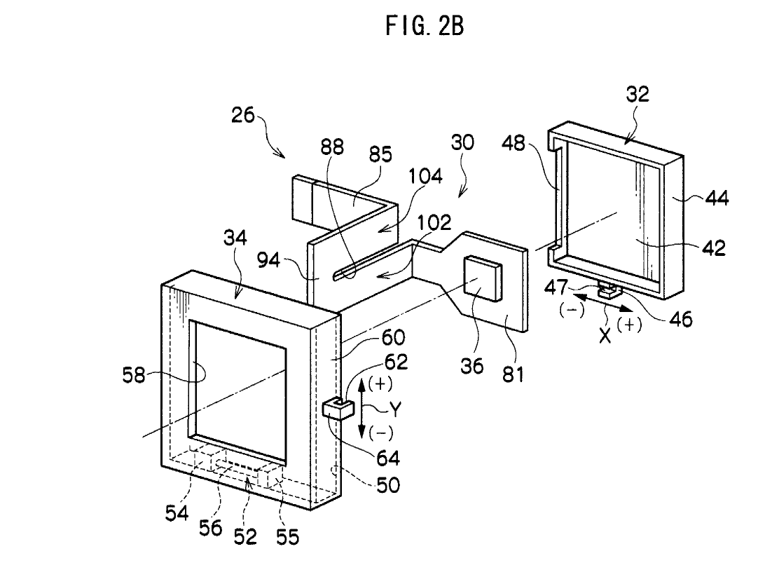

Referring to FIGS. 2A and 2B, the imaging module 26 is constituted by the flexible wiring board 30, a first stage 32 to which the flexible wiring board 30 is fixed and which can be displaced in a direction of an arrow X, and a second stage 34 which can be displaced in a direction of an arrow Y with the first stage 32 being mounted on the inside thereof.

The first stage 32 has a placing portion 42 which is fixed with an adhesive or the like on the surface opposite to the surface on where the CCD 36 on the flexible wiring board 30 is mounted. An engaging portion 46 having an outer shape of nearly U and having a recessed portion 47 formed therein is integrally formed on the outer surface of a side wall 44 arranged on the lower side, which is one of the side walls 44 of the first stage 32 which is erected so as to surround the placing portion 42.

Of the side walls 44, further, on a portion facing the driving circuit 28 there is formed a cut-away portion 48 of a size that meets the width of the flexible wiring board 30. The free end of the flexible wiring board 30 is withdrawn through the cut-away portion 48.

The second stage 34 has a housing portion 50 for housing the first stage 32 therein. A first actuator portion 52 is provided on the bottom surface of the housing portion 50 so as to be driven by the driving circuit 28 in the direction of the arrow X.

The first actuator portion 52 has a driving portion 54 provided with a piezoelectric element (not shown) to which an electric current is fed from the driving circuit 28, and a shaft portion 56 which stretches between the driving portion 54 and a support portion 55 of the shape of a flat plate studded on the bottom surface of the housing portion 50 and is displaced in the direction of the arrow X (positive direction, negative direction) accompanying the displacement of piezoelectric element in the driving portion 54.

The shaft portion 56 is arranged nearly in parallel with the bottom surface of the housing portion 50. The shaft portion 56 has an outer diameter which is nearly equal to the inner diameter of the recessed portion 47 in the engaging portion 46 of the first stage 32. A groove that is not shown is formed in a direction that intersects the axial direction of the shaft portion 56.

Here, the first stage 32 is held in the housing portion 50 of the second stage 34, the recessed portion 47 is engaged with the groove of the shaft portion 56, so that the engaging portion 46 and the shaft portion 56 undergo the displacement integrally together while the first stage 32 is allowed to undergo the displacement in the direction of the arrow X (positive, negative) relative to the second stage 34. A guide rail of nearly an L-shape (not shown) formed in the housing portion 50 is in contact with the upper side wall 44 of the first stage 32 that is held, to thereby hold the first stage 32 in nearly the vertical direction.

The surface of the CCD 36 is exposed in the second stage 34, and an opening 58 is so formed therein so as be opposed to the lens 16 (see FIG. 1). Further, an engaging portion 64 having an outer shape of nearly U and having a recessed portion 62 formed therein is integrally formed on the outer surface of the right side wall 60 of the second stage 34.

Referring to FIG. 2A, on the other hand, a second actuator portion 66 is provided on the inner wall surface of the rear cover 14 so as to be driven by the driving circuit 28 in the direction of the arrow Y The second actuator portion 66 has a driving portion 68 provided with a piezoelectric element (not shown) to which an electric current is fed from the driving circuit 28, and a shaft portion 72 which stretches between the driving portion 68 and a support portion 70 of the shape of a flat plate studded on the inner wall surface of the rear cover 14 and is displaced in the direction of the arrow Y (positive direction, negative direction) by the displacement of piezoelectric element in the driving portion 68.

The shaft portion 72 is arranged nearly in parallel with the inner wall surface of the rear cover 14. The shaft portion 72 has an outer diameter which is nearly equal to the inner diameter of the recessed portion 62 in the engaging portion 64. A groove that is not shown is formed in a direction that intersects the axial direction of the shaft portion 72.

Here, the second stage 34 has its recessed portion 62 engaged with the groove of the shaft portion 72 in a state of holding the first stage 32 and the flexible wiring board 30 therein, so that the engaging portion 64 and the shaft portion 72 undergo the displacement integrally together while the second stage 34 is allowed to undergo the displacement in the direction of the arrow Y (positive, negative) relative to the inner wall surface of the rear cover 14. Here, a guide rail of nearly an L-shape (not shown) formed on the inner wall surface of the rear cover 14 is in contact with the side wall 74 on the left side of the second stage 34 to thereby hold the second stage 34 in nearly the vertical direction.

Referring to FIG. 1, the driving circuit 28 is provided with an acceleration sensor (not shown) to detect the amount of deviation in the directions of arrows X and Y from the original optical axis in case the optical axis of the digital camera 10 is moved in the directions of arrows X and Y due to unintentional movement of the hand of a person who takes a picture.

Depending upon the detected amounts of deviation in the X- and Y-directions, the driving circuit 28 drives the first actuator portion 52 and the second actuator portion 66 to displace the first stage 32 and the second stage 34 in the X- and Y-directions. Therefore, the CCD 36 undergoes the displacement (movement) in the X- and Y-directions on a plane of movement in parallel with the imaging plane of the CCD 36 to thereby correct unintentional movement of the hands holding the digital camera 10.

Next, the flexible wiring board 30 will be described. FIG. 3A illustrates a state where the flexible wiring board 30 of before being folded is viewed from the side on where the CCD 36 is mounted. FIG. 3B illustrates a state where the flexible wiring board 30 after folded is connected to the driving circuit 28.

The flexible wiring board 30 uses, as a base member, a flexible substrate 84 made of a resin such as a polyimide film or a PET film. A plurality of wirings 86 of copper foil are formed on one surface of the flexible substrate 84. The wirings 86 are electrically connecting the terminals (not shown) of the CCD 36 to the terminals of a connection terminal portion 82. A coverlay made of a polyimide film is placed on the surfaces of the wirings 86, and is heated and press-adhered to cover the wirings 86.

The flexible wiring board 30 has a round-ended slit 88 formed on the side of the free end of the flexible substrate 84. The slit 88 divides the flexible substrate 84 into a first flexible portion 90 and a second flexible portion 92 while leaving a relay portion 94 that connects the first flexible portion 90 and the second flexible portion 92 together.

Here, in the flexible substrate 84, the region where the wirings 86 are formed to be a nearly arcuate shape turning round the end of the slit 88 is regarded to be the relay portion 94, and the side of the connection terminal portion 82 is regarded to be the second flexible portion 92 and the side on where the CCD 36 (see FIG. 1) is mounted is regarded to be the first flexible portion 90 with the relay portion 94 as a reference. A first folding line 96 is set in the first flexible portion 90 in a direction at right angles with the wiring direction of the wirings 86. Further, a second folding line 98 is set in the second flexible portion 92 in a direction at right angles with the wiring direction of the wirings 86.

In the first flexible portion 90, the surface of a region on the side opposite to the relay portion 94 with the first folding line 96 as a reference serves as a first mounting surface 81. On the first mounting surface 81 is provided a mounting electrode portion 83 having a plurality of electrode pads arranged to meet the terminals of the CCD 36 (see FIG. 1).

In the second flexible portion 92, the surface of a region on the side opposite to the relay portion 94 with the second folding line 98 as a reference serves as a second mounting surface 85. The connection terminal portion 82 is provided on the second mounting surface 85. Further, prior to being folded along the first folding line 96 and the second folding line 98, the CCD 36 is soldered to the mounting electrode portion 83.

In producing the flexible wiring board 30 as shown in FIG. 3B, the first flexible portion 90 of the flexible substrate 84 is folded along the first folding line 96, and the side of the relay portion 94 is erected to form a first erected surface portion 102. On the other hand, the second flexible portion 92 is folded along the second folding line 98 toward a direction opposite to the first folding line 96, and the side of the relay portion 94 is erected to form a second erected surface portion 104. With the common relay portion 94 being erected, here, the first erected surface portion 102 and the second erected surface portion 104 are arranged on the same plane. The wirings 86 are provided on the first flexible portion 90, on the first erected surface portion 102, on the relay portion 94, on the second erected surface portion 104 and on the second flexible portion 92, though this is not shown in the drawings.

Next, the connection terminal portion 82 is connected being inserted in the connector 29 of the driving circuit 28, and the side of the second mounting surface 85 is fixed. On the other hand, the side of the first mounting surface 81 is fixed being adhered to the first stage 32 (see FIG. 2B). Thereafter, the parts such as the imaging module 26 and lens 16 (see FIG. 1) are mounted to assemble the digital camera 10.

Next, the operation of the first embodiment of the invention will be described. First, a flexible wiring board 300 that has conventionally been used will be described in comparison to the present invention.

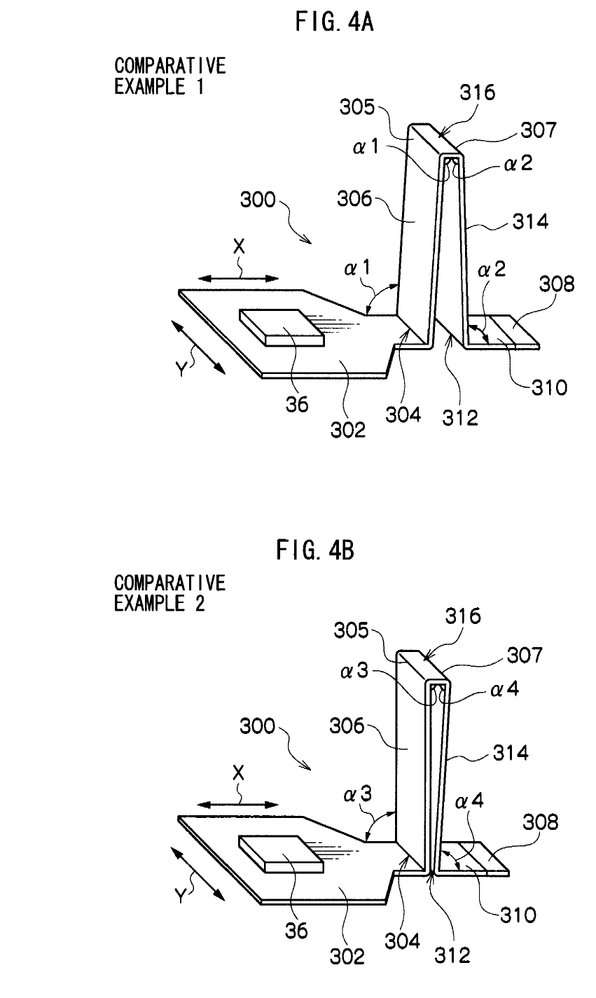

Referring to FIG. 4A, the flexible wiring board 300 of the comparative example is folded along a first folding line 304, and a first erected surface portion 306 is erected from a first mounting surface 302 on which the CCD 36 is mounted. The flexible wiring board 300 is, further, folded along a second folding line 312, and a second erected surface portion 314 is erected from a second mounting surface 310 on where a connection terminal portion 308 is provided. The first erected surface portion 306 and the second erected surface portion 314 are folded along a third folding line 305 and a fourth folding line 307, respectively, to thereby form a relay portion 316.

The CCD 36 (first mounting surface 302) moves in the directions of X-axis and Y-axis being driven by an actuator of the imaging module that is not shown, and the connection terminal portion 308 is connected and fixed to a connector of a driving circuit (not shown) that drives the imaging module.

First, the directions and the positions of origins are defined. The direction in which the CCD 36 and the connection terminal portion 308 are arranged is regarded to be the X-axis direction, the direction in which the CCD 36 and the connection terminal portion 308 approach each other is regarded to be the plus (X+) direction, and the direction in which they separate away from each other is regarded to be the minus (X−) direction. In the X-axis direction, further, the positions (positions of origins) where the CCD 36 and the connection terminal portion 308 are first set are the positions where the angle formed between the first erected surface portion 306 and the relay portion 316 is 90° and where the angle formed between the second erected surface portion 314 and the relay portion 316 is 90°.

Further, the reaction force acting in a direction in which the gap between the CCD 36 and the connection terminal portion 308 is widened is regarded to be the plus (P+) reaction force and the reaction force acting in a direction in which the gap is narrowed is regarded to be the minus (P−) reaction force. The direction that intersects the X-axis at right angles is the Y-axis direction.

As a first pattern of the folded angles of the flexible wiring board 300 of the comparative example, it is presumed here that the angle formed between the first erected surface portion 306 and the relay portion 316 is α1 (90°<α1<180°), and the angle formed between the second erected surface portion 314 and the relay portion 316 is α2 (90°<α2<180°).

If the flexible wiring board 300 in this state is arranged on the above positions of origins, the side of the connection terminal portion 308 has been fixed and, therefore, the plus reaction force (PB+) acts from the first erected surface portion 306 to the first mounting surface 302 so as to return to the initial positions by expanding the gap between the CCD 36 and the connection terminal portion 308. Further, if the CCD 36 is brought close to the connection terminal portion 308 in the (X+) direction from the position of origin, an increased plus reaction force acts on the first mounting surface 302 from the first erected surface portion 306, and the reaction force assumes P1+.

Conversely, if the CCD 36 separates away from the connection terminal portion 308 in the (X−) direction from the position of origin, the plus reaction force decreases and the reaction force of the X-axis direction becomes approximately zero at a position where the angle formed between the first erected surface portion 306 and the relay portion 316 is α1 and the angle formed between the second erected surface portion 314 and the relay portion 316 is α2. If the CCD 36 further separates away in the (X−) direction, then a minus reaction force (P1−) acts so as to return to the initial position by narrowing the gap between the CCD 36 and the connection terminal portion 308.

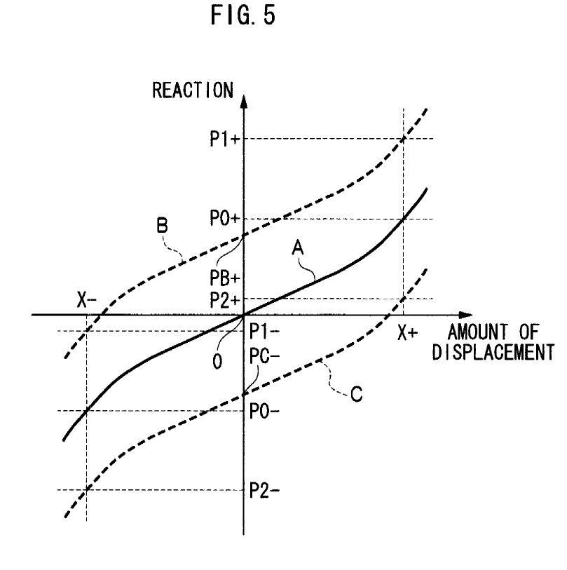

FIG. 5 is a graph illustrating a relationship between the amount of displacement in the X-axis direction and the reaction force that acts on the first folding line 304 and the second folding line 312. In folding the first folding line 304 and the second folding line 312 in FIG. 5, if the angle formed between the first erected surface portion 306 and the relay portion 316 becomes α1 and the angle formed between the second erected surface portion 314 and the relay portion 316 becomes α2, then the relationship between the amount of displacement in the X-axis direction and the reaction force becomes as represented by a curve B.

As a second pattern of the folded angles of the flexible wiring board 300 of another comparative example as shown in FIG. 4B, it is presumed here that the angle formed between the first erected surface portion 306 and the relay portion 316 is α3 (0°<α3<90°), and the angle formed between the second erected surface portion 314 and the relay portion 316 is α4 (0°<α4<90°).

If the flexible wiring board 300 in this state is arranged on the above positions of origins, a minus reaction force (PC−) acts on the third folding line 305 and the fourth folding line 307 so as to return to the initial positions by narrowing the gap between the CCD 36 and the connection terminal portion 308.

Here, if the CCD 36 is brought close to the connection terminal portion 308 in the (X+) direction from the position of origin, the minus reaction force decreases and the reaction force becomes zero in the X-axis direction at a position where the angle formed between the first erected surface portion 306 and the relay portion 316 is α3 and the angle formed between the second erected surface portion 314 and the relay portion 316 is α4. If the CCD 36 is further brought close to the connection terminal portion 308 in the (X+) direction from the position of origin, the plus reaction force acting on the third folding line 305 and the fourth folding line 307 increases and the reaction force becomes P2+.

Conversely, if the CCD 36 separates away from the connection terminal portion 308 in the (X−) direction from the position of origin, a further minus reaction force acts so as to return the CCD to the initial position by narrowing the gap between the CCD 36 and the connection terminal portion 308, and the reaction force becomes P2−. At the time of folding as described above, if the angle formed between the first erected surface portion 306 and the relay portion 316 becomes α3 and the angle formed between the second erected surface portion 314 and the relay portion 316 becomes α4, then the relationship between the amount of displacement in the X-axis direction and the reaction force is as represented by curve C.

The first and second patterns of folding angles of comparative examples could both occur in the step of really assembling the flexible wiring board 300. When the flexible wiring boards 300 of comparative examples are used, therefore, a large thrust must be imparted that is not affected by the reaction force over a wide range of from P2− to P1+ in order that the CCD 36 undergoes the displacement (movement) over ±X with respect to the connection terminal portion 308. This, however, causes means for moving the CCD 36 to become bulky requiring an increased amount of energy for the movement and, besides, making it difficult to decrease the size.

Though in the foregoing was discussed the movement of the CCD 36 in the X-axis direction in comparative examples, the reaction force also acts on the relay portion 316 due to the twisting force when the CCD 36 moves in the Y-axis direction, too, since the first erected surface portion 306 moves in a direction that is deviated relative to the second erected surface portion 314 at all times. Therefore, the moving means must give a large thrust that is not affected by the reaction force.

With the flexible wiring board 30 of the present invention as shown in FIG. 3B, on the other hand, when the CCD 36 is moved in the X-axis direction, the force in the X-axis direction acts on the first mounting surface 81 and on the second mounting surface 85 via the ends thereof. Here, the first erected surface portion 102 and the second erected surface portion 104 are arranged on the same plane. In the relay portion 94, therefore, the force in the X-axis direction acts as a force from the direction outside of the plane.

The relay portion 94 is more readily bent when the force acts from the direction outside of the plane of the relay portion 94 than when the force acts from the direction inside of the plane thereof. With the relay portion 94 being bent, therefore, a suppressed reaction force acts on the first mounting surface 81 and on the second mounting surface 85 from the first erected surface portion 102 and the second erected surface portion 104.

Here, the magnitude of the reaction force of the flexible wiring board 30 due to the displacement in the X-axis direction can be represented by a curve A in FIG. 5. As will be understood from the comparison of curves A, B and C in FIG. 5, when the flexible wiring board 30 of the invention is displaced in the X-axis direction over ±X, the range of reaction force that affects the movement of the CCD 36 is from P0− to P0+ decreasing the thrust required to move the CCD 36 of the flexible wiring boards 300 of the comparative examples. This makes it possible to decrease the size of means for moving the CCD 36.

Further, if a force in the Y-axis direction acts on the first mounting surface 81 and the second mounting surface 85 via the first erected surface portion 102 and the second erected surface portion 104 in parallel with the first folding line 96 and the second folding line 98, then a force acts on the relay portion 94 in the direction inside of the plane. Here, however, since the first erected surface portion 102 and the second erected surface portion 104 can be displaced in the direction inside of the plane by the size of the slit 88, a suppressed reaction force acts on the first mounting surface 81 and on the second mounting surface 85 from the first erected surface portion 102 and from the second erected surface portion 104. This suppresses the reaction force that affects the movement of the CCD 36 in the Y-axis direction as compared to comparative examples.

According to the flexible wiring board 30 of the invention as described above, the first erected surface portion 102 and the second erected surface portion 104 are positioned on the same plane suppressing the reaction force that acts on the first mounting surface 81 and on the second mounting surface 85 in the directions of X-axis and Y-axis inside of the plane thereof. This improves the precision for moving the CCD 36 for correcting unintentional movement of the hands holding the digital camera 10, and improves the precision for correcting the unintentional movement of the hand holding the digital camera 10. Further, since the reaction force is not likely to act on the mounting electrode portion 83 mounting the CCD 36 or on the connection terminal portion 82, when, for example, means for moving the CCD 36 is a motor, the output of the motor can be suppressed and, therefore, the size of the motor can be decreased making it possible to realize the digital camera 10 in a small size.

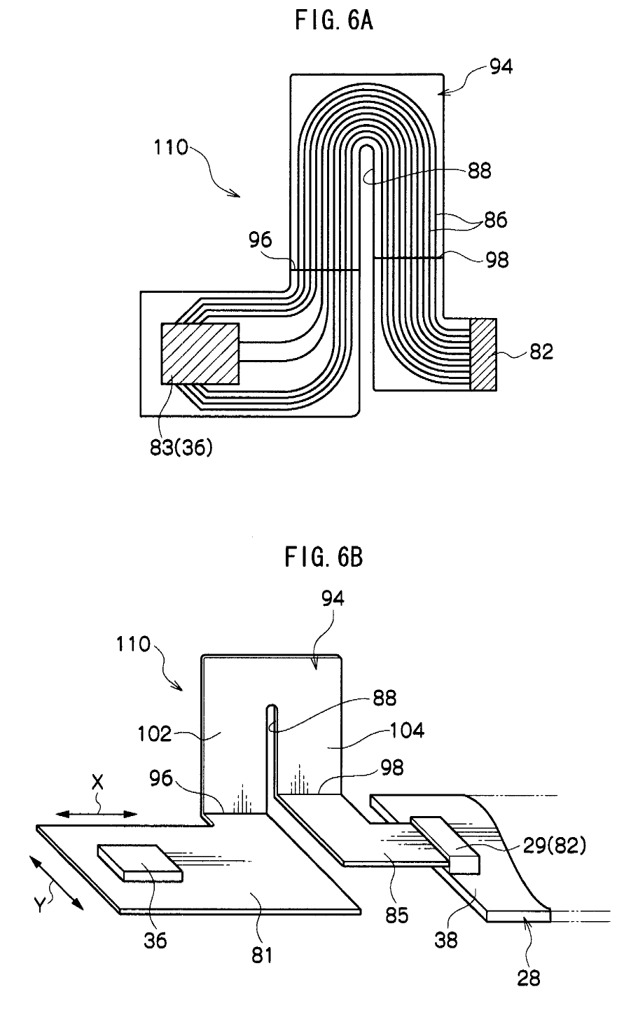

FIGS. 6A and 6B illustrate a flexible wiring board 110 according to another example of the first embodiment. The flexible wiring board 110 is of a shape in which the relay portion 94 of the flexible wiring board 30 is arranged on the side of the Y-axis direction.

In the flexible wiring board 110, the first erected surface portion 102 and the second erected surface portion 104 are positioned on the same plane suppressing the reaction force that acts on the first mounting surface 81 and on the second mounting surface 85 when moving in the Y-axis direction or when at rest. Further, since the first erected surface portion 102 and the second erected surface portion 104 are allowed to freely move by the size of the slit 88, a suppressed reaction force acts on the first mounting surface 81 and on the second mounting surface 85 when moving in the X-axis direction or when at rest.

Next, the flexible wiring board and the imaging device according to a second embodiment of the invention will be described with reference to the drawings. Here, the fundamentally same portions as those of the above first embodiment are denoted by the same reference numerals as those of the first embodiment and their description is not repeated.

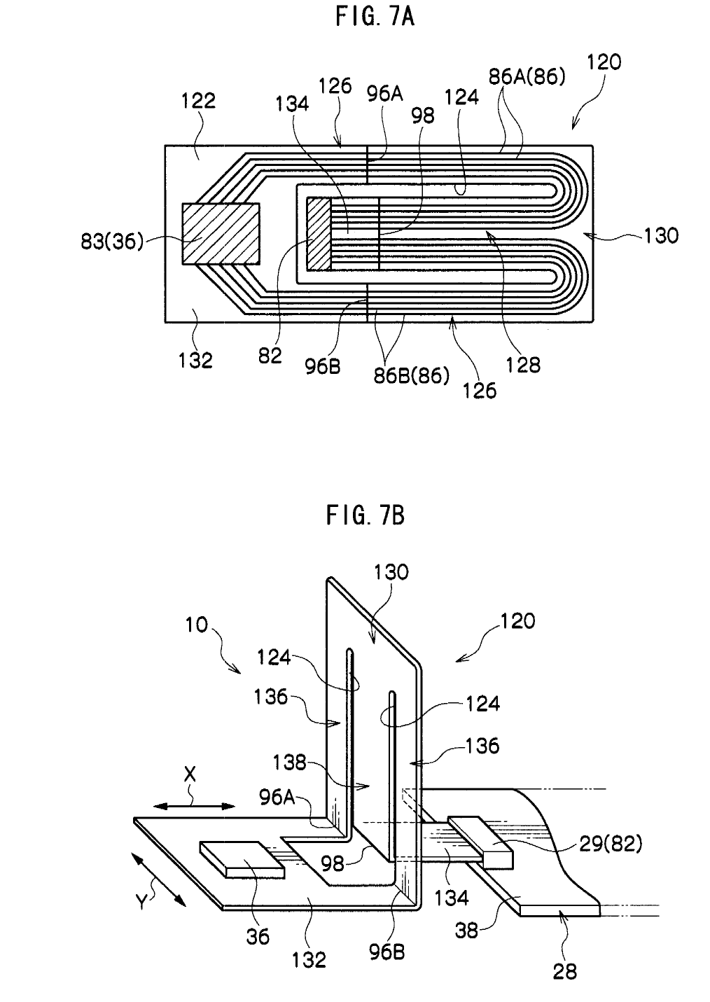

FIGS. 7A and 7B illustrate a flexible wiring board 120. The flexible wiring board 120 uses, as a base member, a flexible substrate 122 made of a resin such as a polyimide film or a PET film. The flexible wiring board 120 has a U-shaped slit 124 formed in the flexible substrate 122 by stamping.

The slit 124 divides the flexible substrate 122 into a first flexible portion 126 and a second flexible portion 128 while leaving a relay portion 130 that connects the first flexible portion 126 and the second flexible portion 128 together. The outer side of the slit 124 is the first flexible portion 126 and the inner side thereof is the second flexible portion 128.

The mounting electrode portion 83 is provided on the first flexible portion 126 to mount the CCD 36 (see FIG. 1) thereon by soldering. The connection terminal portion 82 is provided at an end of the second flexible portion 128 for connection to a driving circuit (not shown) for driving the CCD 36. The mounting electrode portion 83 and the connection terminal portion 82 are electrically connected together by wirings 86 (86A, 86B). The wirings 86 are arranged being divided for the two first flexible portions 126.

First folding lines 96A and 96B are set in the first flexible portions 126 in a direction at right angles with the wiring direction of the wirings 86A and 86B, and the second folding line 98 is set in the second flexible portion 128 in a direction at right angles with the wiring direction of the wirings 86A and 86B.

In the first flexible portion 126, the surface of a region on the side opposite to the relay portion 130 with the first folding lines 96A and 96B as a reference serves as a first mounting surface 132. In the second flexible portion 128, further, the surface of a region on the side opposite to the relay portion 130 with the second folding line 98 as a reference serves as a second mounting surface 134. The CCD 36 is soldered to the mounting electrode portion 83 prior to folding the flexible substrate 122 along the first folding lines 96A, 96B and the second folding line 98.

In producing the flexible wiring board 120 as shown in FIG. 7B, the first flexible portions 126 are folded along the first folding lines 96A and 96B, and the side of the relay portion 130 is erected to form a first erected surface portion 136. On the other hand, the second flexible portion 128 is folded along the second folding line 98 toward a direction opposite to the first folding lines 96A and 96B, and the side of the relay portion 130 is erected to form a second erected surface portion 138. With the common relay portion 130 being erected, here, the first erected surface portions 136 and the second erected surface portion 138 are arranged on the same plane. The wirings 86 are not shown here.

Next, the connection terminal portion 82 is connected being inserted in the connector 29 of the driving circuit 28, and the side of the second mounting surface 134 is fixed. On the other hand, the side of the first mounting surface 132 is fixed being adhered to the first stage 32 (see FIG. 2B). Thereafter, the parts such as the imaging module 26 and lens 16 (see FIG. 1) are mounted to assemble the digital camera 10.

Next, the operation of the second embodiment of the invention will be described.

With the flexible wiring board 120 as shown in FIG. 7B, when the CCD 36 is moved in the X-axis direction, the force in the X-axis direction acts on the first mounting surface 132 and on the second mounting surface 134 via the ends thereof. Here, the first erected surface portions 136 and the second erected surface portion 138 are arranged on the same plane. In the relay portion 130, therefore, the force in the X-axis direction acts as a force from the direction outside of the plane.

The relay portion 130 is more readily bent when the force acts from the direction outside of the plane of the relay portion 130 than when the force acts from the direction inside of the plane thereof. With the relay portion 130 being bent, therefore, a suppressed reaction force acts on the first mounting surface 132 and on the second mounting surface 134 from the first erected surface portions 136 and the second erected surface portion 138.

As for the Y-axis direction of the flexible wiring board 120, when the CCD 36 is moved in the Y-axis direction, the first erected surface portion 136 and the second erected surface portion 138 are allowed to freely undergo the displacement in the direction inside of the plane inclusive of the first erected surface portions 136 and the second erected surface portion 138 by the size of the slits 124 at two places. Therefore, a suppressed reaction force acts on the first mounting surface 132 and on the second mounting surface 134 from the first erected surface portions 136 and the second erected surface portion 138.

Further, since the wirings 86 are divided into wirings 86A and 86B, the divided wirings 86A and 86B possess a decreased width. Therefore, the relay portion 130 has a decreased width, the slit 126 has an increased length, and the reaction force (load) decreases when the first flexible portions 126 and the second flexible portion 128 relatively move in the Y-axis direction enabling the CCD 36 to easily move in the Y-axis direction.

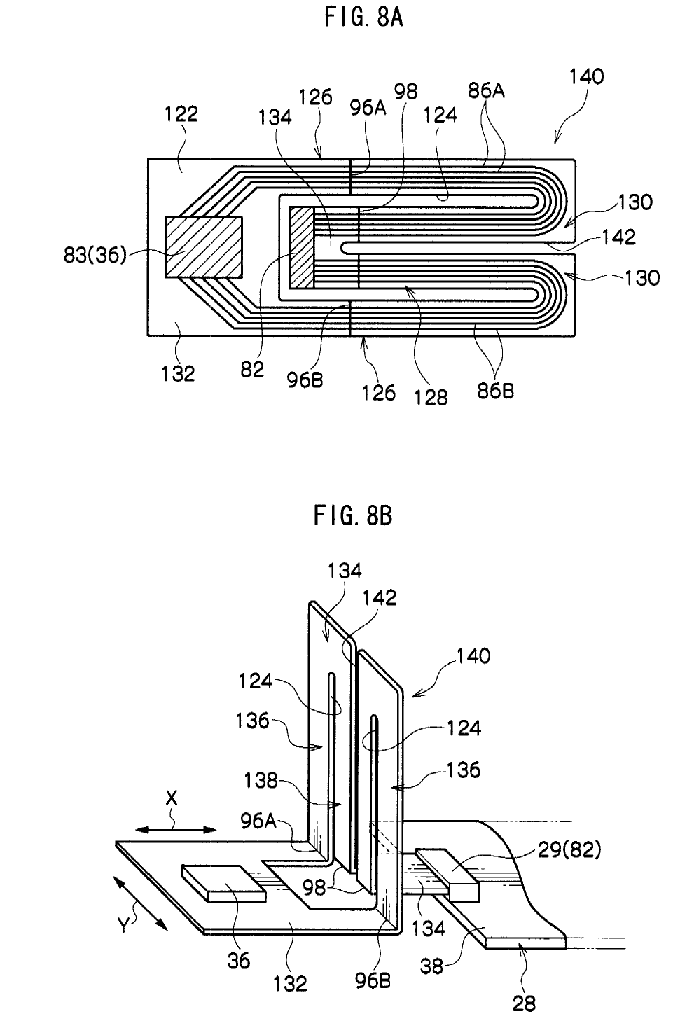

FIGS. 8A and 8B illustrate a flexible wiring board 140 according to another example of the second embodiment. The flexible wiring board 140 is formed by cutting at the central portion of the second flexible portion 128 from the relay portion 130 of the flexible wiring board 120 to thereby form an auxiliary slit 142 leaving the second mounting surface 134. Wirings 86A and 86B are formed on both sides of the auxiliary slit 142.

The flexible wiring board 140 is capable of suppressing the reaction force in the X-axis direction like the above flexible wiring board 120 (see FIGS. 7A and 7B). As for the reaction force in the Y-axis direction, the slits in the direction in which the second flexible portion 128 moves (Y-axis direction) include a total of three slits, i.e., two slits 124 and the auxiliary slit 142. Therefore, the second moving portion 128 is allowed to freely move (relatively move) accompanying the movement of the first flexible portions 126 by the sizes of the three slits suppressing the reaction force that acts on the CCD 36 when it moves.

Next, the flexible wiring board and the imaging device according to a third embodiment of the invention will be described with reference to the drawings. Here, the fundamentally same portions as those of the above first and second embodiments are denoted by the same reference numerals as those of the first and second embodiments and their description is not repeated.

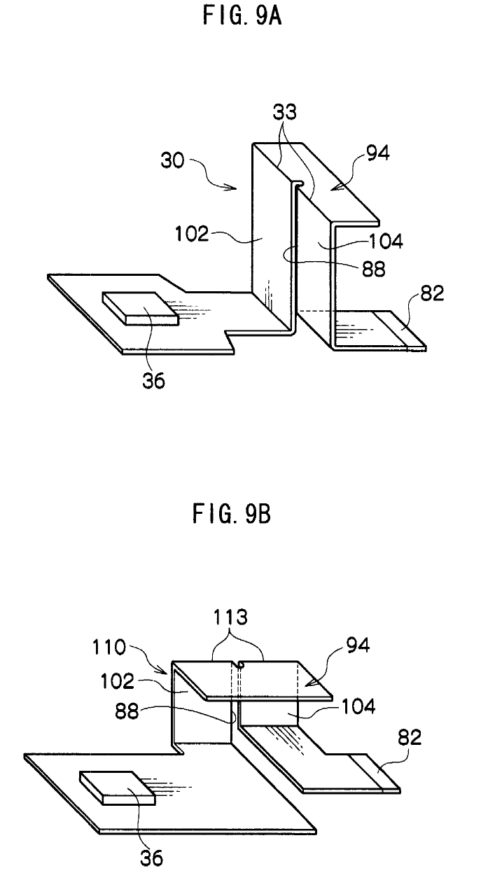

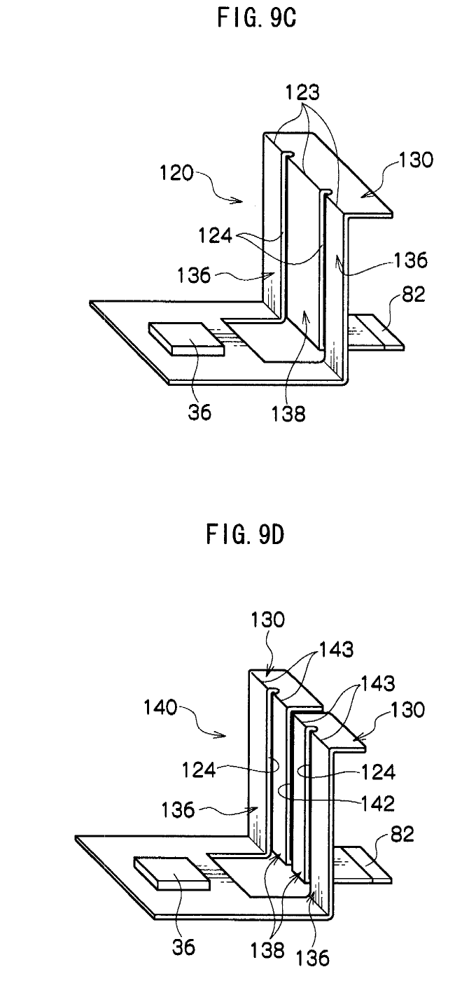

FIG. 9A illustrates a state where in the above flexible wiring board 30, a third folding line 33 is provided on an upper part of the first erected surface portion 102 and on an upper part of the second erected surface portion 104 traversing the slit 88, and is folded at about 90°. Similarly, FIG. 9B illustrates a state where in the above flexible wiring board 110, a third folding line 33 is provided on an upper part of the first erected surface portion 102 and on an upper part of the second erected surface portion 104 traversing the slit 88, and is folded at about 90°.

FIG. 9C illustrates a state where, in the flexible wiring board 120, a third folding line 123 is provided on upper parts of the first erected surface portions 136 and on an upper part of the second erected surface portion 138 traversing the slits 124, and is folded at about 90°. FIG. 9D illustrates a state where in the flexible wiring board 140, a third folding line 143 is provided on upper parts of the first erected surface portions 136 and on upper parts of the second erected surface portions 138 traversing the slits 124 and the auxiliary slit 142, and is folded at about 90°.

Next, the operation of the third embodiment of the invention will be described.

As shown in FIGS. 9A to 9D, the flexible wiring boards 30, 110, 120 and 140 are folded at about 90° along the third folding lines 33, 113, 123 and 143. Therefore, the slit 88, slits 124 and auxiliary slit 142 are all present in the regions of the first erected surface portions 102, 136 and of the second erected surface portions 104, 138 from the lower ends up to the upper ends.

Therefore, when the CCD 36 and the connection terminal portion 82 move in a direction intersecting the slits, restraint of the movement by the reaction force due to the rigidity of the relay portion 94 or the relay portion 130 is suppressed, and a decreased load (reaction force) is exerted when the CCD 36 moves.

Next, the flexible wiring board and the imaging device according to a fourth embodiment of the invention will be described with reference to the drawings. Here, the fundamentally same portions as those of the above first embodiment are denoted by the same reference numerals as those of the first embodiment and their description is not repeated.

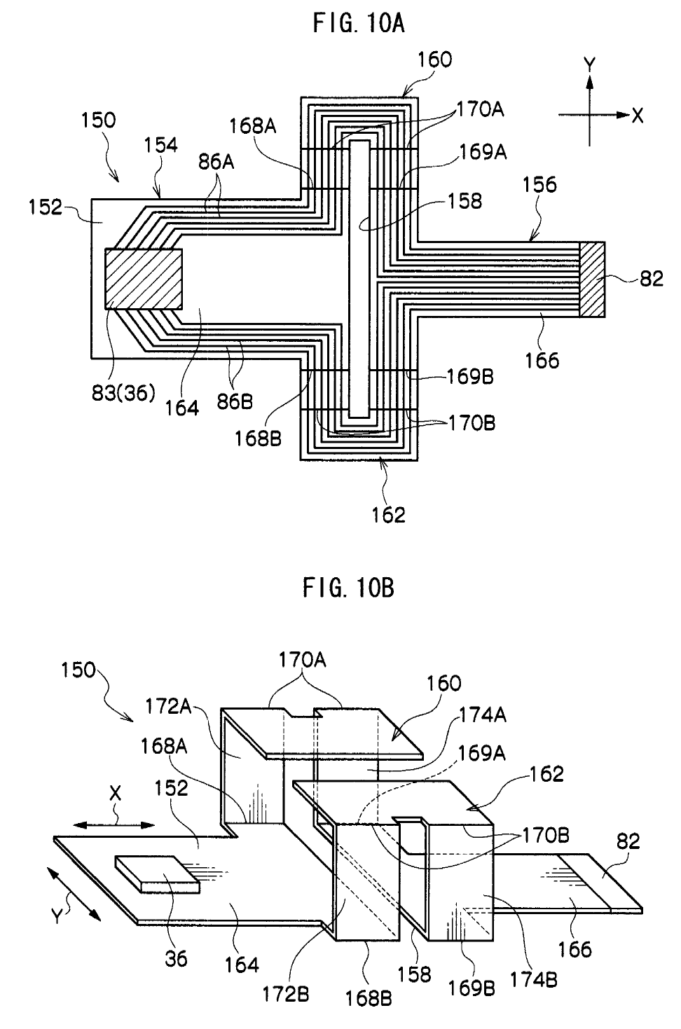

FIG. 10A illustrates a state where a flexible wiring board 150 before being folded is viewed from the side of the surface on which the CCD 36 is mounted. FIG. 10B illustrates the shape of the flexible wiring board 150 after being folded.

The flexible wiring board 150 uses, as a base member, a flexible substrate 152 made of a resin such as a polyimide film or a PET film. The flexible substrate 152 has nearly a crossing outer shape on the XY-plane, the left side in the right-and-left direction (X-axis direction) being the first flexible portion 154 and the right side being the second flexible portion 156.

A rectangular slit 158 is formed in the longitudinal direction (Y-axis direction) between the first flexible portion 154 and the second flexible portion 156. Two relay portions 160 and 162 are provided at both ends of the slit 158 in the lengthwise direction thereof to connect the first flexible portion 154 and the second flexible portion 156 together.

The mounting electrode portion 83 on which the CCD 36 is to be mounted is provided on a first mounting surface 164 of the first flexible portion 154, and the connection terminal portion 82 is provided at an end of a second mounting surface 166 of the second flexible portion 156. The mounting electrode portion 83 and the connection terminal portion 82 are electrically connected together through wirings 86A and 86B.

In the regions where the first flexible portion 154 and the second flexible portion 156 oppose via the slit 158, first folding lines 168A and 168B are provided in the first flexible portion 154 in a direction (X-axis direction) at right angles with the wirings 86A and 86B. Further, second folding lines 169A and 169B are provided in the second flexible portion 156 in a direction (X-axis direction) at right angles with the wirings 86A and 86B. Further, third folding lines 170A and 170B are provided in the first flexible portion 154 and in the second flexible portion 156 on the sides of the relay portions 160 and 162. The CCD 36 is soldered onto the mounting electrode portion 83 before the first folding lines 168A, 168B, second folding lines 169A, 169B, and third folding lines 170A, 170B are folded.

In producing the flexible wiring board 150 as shown in FIG. 10B, the flexible substrate 152 is folded along the first folding lines 168A, 168B, second folding lines 169A, 169B and third folding lines 170A, 170B to thereby form first erected surface portions 172A, 172B and second erected surface portions 174A, 174B, and the relay portion 160 and the relay portion 162 are arranged being opposed to each other. The first erected surface portion 172A and the second erected surface portion 174A are arranged on the same plane, and the first erected portion 172B and the second erected surface portion 174B are arranged on another same plane.

Next, the connection terminal portion 82 is connected being inserted in the connector 29 (see FIG. 1) of the driving circuit 28, and the side of the second mounting surface 166 is fixed. On the other hand, the side of the first mounting surface 164 is fixed being adhered to the first stage 32 (see FIG. 2B). Thereafter, the parts such as the imaging module 26 and lens 16 (see FIG. 1) are mounted to assemble the digital camera 10. The wirings are not shown here.

Next, the operation of the fourth embodiment of the invention will be described.

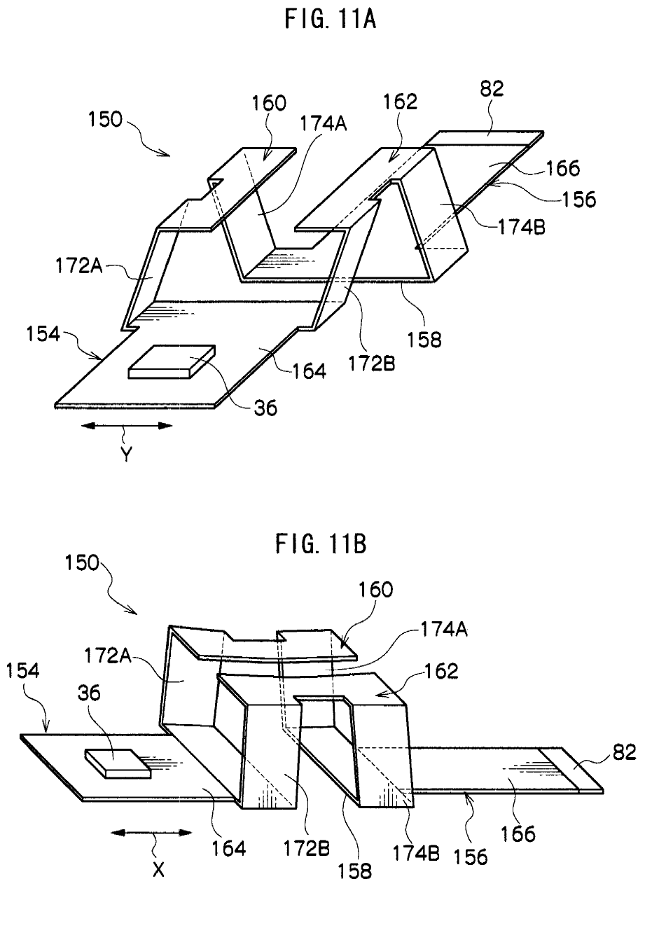

Referring to FIG. 11A, when the CCD 36 moves in the Y-axis direction, the force acting in the Y-axis direction is a force from the direction outside of the planes of the first erected surface portion 172A, second erected surface portion 174A, first erected surface portion 172B and second erected surface portion 174B since the first erected surface portion 172A and the second erected surface portion 174A are on the same plane, and the first erected surface portion 172B and the second erected surface portion 174B are on another same plane.

Due to the force in the direction outside of the planes, a set of opposing first erected surface portion 172A and first erected surface portion 172B and a set of opposing second erected surface portion 174A and second erected surface portion 174B easily undergo deformation in the shape of a parallelogram, respectively. Thus, the CCD 36 can be moved without being imparted with an excess of reaction force (load) thereto.

Referring to FIG. 11B, when the CCD 36 moves in the X-axis direction, on the other hand, the first flexible portion 154 can be easily moved by the size of the slit 158 suppressing the reaction force.

Next, the flexible wiring board and the imaging device according to a fifth embodiment of the invention will be described with reference to the drawings. Here, the fundamentally same portions as those of the above first embodiment are denoted by the same reference numerals as those of the first embodiment and their description is not repeated.

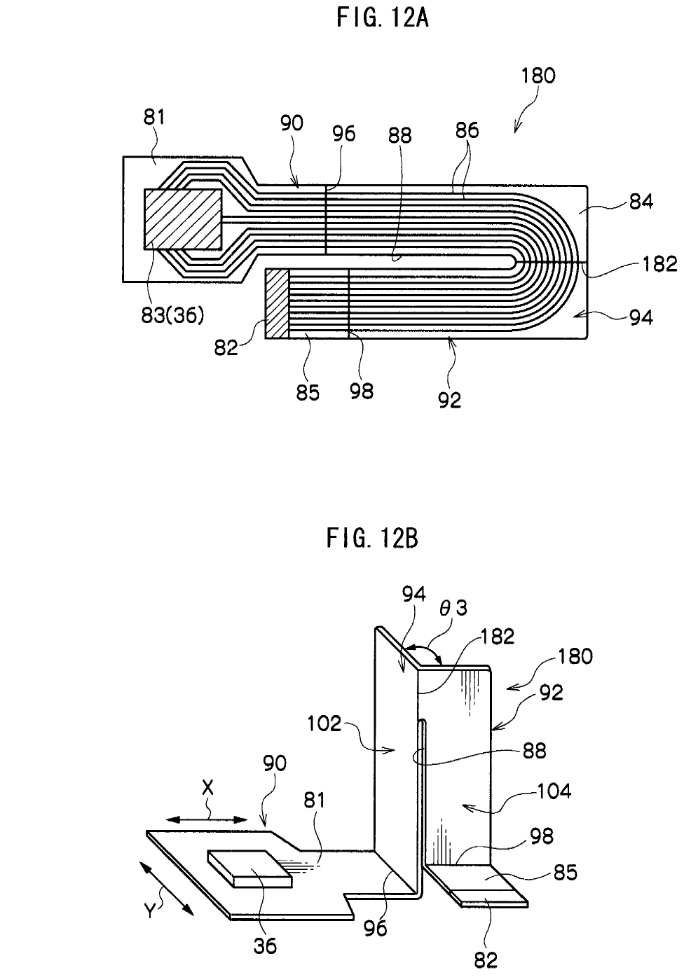

Referring to FIG. 12A, a flexible wiring board 180 of the fifth embodiment has a folding line 182, which serves as the relay portion 94, in a length direction of the slit 88 in the flexible wiring board 30 (see FIGS. 3A and 3B). Referring to FIG. 12B, further, the flexible wiring board 180 is folded along the folding line 182 so that the angle θ3 subtended by the first erected surface portion 102 and the second erected surface portion 104 is the right angle (90°) or an angle close to the right angle. None of the driving circuit, imaging module or wirings is shown here.

Next, the operation of the fifth embodiment of the invention will be described.

In the flexible wiring board 180, the angle formed between the first erected surface portion 102 and the second erected surface portion 104 is the right angle (or is an angle close to the right angle). Therefore, when the CCD 36 on the first flexible portion 90 is moved in the X-axis direction and in the Y-axis direction, the movement of the first erected surface portion 102 is not readily interrupted by the second erected surface portion 104. When the CCD 36 moves, therefore, a reaction force that acts on the first flexible portion 90 and the second flexible portion 92 is suppressed. Therefore, the CCD 36 on the first flexible portion 90 can be easily moved.

The present invention is not limited to the above embodiments only. In addition to the digital cameras, the flexible wiring boards can be further applied to various electronic devices such as timepieces, notebook personal computers, printers, etc. Further, the folding lines in the flexible substrates do not necessarily have to be set in a direction at right angles with the wirings, but their directions may be suitably modified depending upon the outer shapes of the flexible substrates or the wiring patterns on the flexible substrates. Besides, the first folding line and the second folding line may or may not be on the same straight line. In addition to the CCD, furthermore, it is allowable to use an imaging element of the CMOS type or any other imaging element.

What is claimed is:

1. A flexible wiring board comprising:
a flexible substrate including a first flexible substrate portion and a second flexible substrate portion divided by a slit and connected by a relay substrate portion,
the first flexible substrate portion including a first fold and a first erected surface portion which is provided on the side of the relay substrate portion relative to the first fold, and which is erected from the first fold,
the second flexible substrate portion including a second fold and a second erected surface portion which is provided on the side of the relay substrate portion relative to the second fold, and which is erected from the second fold;
a first mounting surface provided at a side opposite to the first erected surface portion relative to the first fold and on which a first electrode is mounted;
a second mounting surface provided at a side opposite to the second erected surface portion relative to the second fold and on which a second electrode is mounted; and
a wiring portion which is mounted on the first mounting surface, the first erected surface portion, the relay substrate portion, the second erected surface portion and the second mounting surface, and which connects the first electrode to the second electrode.

2. The flexible wiring board according to claim 1, wherein the slit is formed in a U-shape, the second flexible substrate portion is positioned on the inner side of the U-shaped slit, the first flexible substrate portion is positioned on the outer side of the U-shaped slit, and the wiring portion is divided into two groups on the first flexible substrate portion.

3. The flexible wiring board according to claim 2, wherein an auxiliary slit is formed cutting into the central portion of the second flexible substrate portion from the relay substrate portion to the second mounting surface, and the wiring portions are formed on both sides of the auxiliary slit.

4. The flexible wiring board according to claim 1, wherein a third fold is provided in the upper part of the first erected surface portion and in the upper part of the second erected surface portion and that traverses the slit.

5. The flexible wiring board according to claim 1, wherein the relay substrate portion is provided at respective ends of the slit to connect the first flexible substrate portion and the second flexible substrate portion, and the wiring portion is divided between the respective relay substrate portions.

6. The flexible wiring board according to claim 1, wherein the relay substrate is folded along the lengthwise direction of the slit, and an angle formed between the first erected surface portion and the second erected surface portion is substantially a right angle.

7. An imaging device comprising: the flexible wiring board of claims 1, an imaging element connected to the first electrode; a driving unit connected and fixed to the second electrode that drives the imaging element; and a moving unit that moves the imaging element in two axial directions on a plane of movement.

8. A method of producing a flexible wiring board comprising:
providing a flexible substrate;
forming a slit in the flexible substrate that divides the flexible substrate into a first flexible substrate portion and a second flexible substrate portion, but leaves a relay substrate portion that connects the first flexible substrate portion to the second flexible substrate portion;
providing a first fold on the first flexible substrate portion, erecting a portion of the first flexible substrate portion on the side of the relay substrate portion relative to the first fold to form a first erected surface portion, and providing a first mounting surface on a side opposite the first erected surface portion relative to the first fold, on which a first electrode is provided;
providing a second fold on the second flexible substrate portion, erecting a portion of the second flexible substrate portion on the side of the relay substrate portion relative to the second fold to form a second erected surface portion, and providing a second mounting surface on a side opposite the second erected surface portion relative to the second fold on which a second electrode is provided; and
providing a wiring portion on the first mounting surface, the first erected surface portion, the relay substrate portion, the second erected surface portion and the second mounting surface to connect the first electrode to the second electrode.

9. The method of producing a flexible wiring board according to claim 8, wherein the slit has a U-shape, the second flexible substrate portion is positioned on the inner side of the U-shaped slit, the first flexible substrate portion is positioned on the outer side of the U-shaped slit, and the wiring portion is divided into two groups on the first flexible substrate portion.

10. The method of producing flexible wiring board according to claim 9, wherein an auxiliary slit is formed cutting into the central portion of the second flexible substrate portion from the relay substrate portion to the second mounting surface, and the wiring portions are formed on both sides of the auxiliary slit.

11. The method of producing a flexible wiring board according to claim 8, wherein a third fold is provided by folding the upper part of the first erected surface portion and the upper part of the second erected surface portion and that traverses the slit.

12. The method of producing a flexible wiring board according to claim 8, wherein the relay substrate portion is provided at respective ends of the slit to connect the first flexible substrate portion and the second flexible substrate portion, and the wiring portion is divided between the respective relay substrate portions.

13. The method of producing a flexible wiring board according to claim 8, wherein the relay substrate is folded along the lengthwise direction of the slit, and an angle formed between the first erected surface portion and the second erected surface portion is substantially a right angle.
